(19) United States
(12) Patent Application Publication
(10) Pub. No.: US 2008/0117362 A1
(43) Pub. Date: May 22, 2008

(54) Organic Light Emitting Diode Devices With Optical Microstructures

(75) Inventors: Martin B. Wolk, Woodbury, MN (US); Vadim Savvateev, St. Paul, MN (US); Manoj Nirmal, St. Paul, MN (US); Thomas R. Hoffend, Woodbury, MN (US); Fred B. McCormick, Maplewood, MN (US); John C. Nelson, The Sea Ranch, CA (US); David A. Engler, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/561,997

(22) Filed: Nov. 21, 2006

(51) Int. Cl. G02F 1/1335; H01L 51/54; H01J 9/02

(52) U.S. Cl. 349/69; 313/504; 445/24

(57) ABSTRACT

Edge-emitting organic light emitting diode (OLED) devices having optical microstructures and methods for fabricating them. The edge-emitting OLEDs include a substrate, an organic electroluminescent layer overlaying the substrate surface, and optical microstructures functioning as turning optics and separated from the OLEDs. The turning optics reflect and redirect the light from the edge-emitting OLEDs away from the top of the substrate, or through and away from the bottom of the substrate.

### FIELD OF INVENTION

The present invention relates to edge-emitting organic light emitting diode (OLED) devices with optical microstructures and methods to make them.

### BACKGROUND

Solid-state lighting uses light-emitting diodes (LEDs) or OLEDs as the light source instead of the traditional incandescent and fluorescent light bulbs. LEDs or OLEDs provide for much higher energy efficiency than incandescent and fluorescent lighting, which can result in significant energy savings through a reduction in consumption of electricity. They can also provide for many more lighting effects. For example, they can be formed in a flexible substrate and thus formed around three-dimensional objects. Also, they can be controlled to selectively provide various colors of lights.

One challenge of solid-state lighting is the light extraction of the LEDs or OLEDs. Significant losses of light occur as a result of lightguiding in the substrate due to total internal reflection (TIR) and waveguiding losses in the high index layers. Losses due to TIR are typically resolved using conventional methods of antireflection, such as index gradients, surface or bulk diffusers, multilayered optical stacks, and microlenses. However, the solution to the loss of approximately 50% of light in waveguided modes is more difficult. The high optical index organic and transparent conductive oxide (TCO) layers of an OLED act similar to an optical fiber with a glass cladding. Evanescent modes emitted into the device plane are trapped within this layer and travel only a very short distance before self-absorption and conversion of the optical energy into heat.

Certain approaches to address lightguiding in solid-state lighting have been developed. These solutions to extracting this light include the use of a low index hydrophobic aerogel layer between the indium tin oxide (ITO) and glass, the use of distributed feedback (DFB) gratings, and the optimization of microcavity effects.

Another approach includes use of two-dimensional (2D) photonic crystal gratings at the high index TCO/glass interface (related to the DFB gratings). This method was initially developed for extracting light from inorganic LEDs and has been modified for OLEDs. This method involves use of photolithography to pattern a regular array of nanoholes in the glass substrate and filling them with high index silicon nitride. Finally, ITO matched to the silicon nitride is deposited to complete the substrate.

Yet another approach involves use of fluorescent dye elements to trap edge-emitted light. This method consists of an array of standard OLEDs configured in stripes that are interspersed with stripes of fluorescent material. The fluorescent material absorbs any edge-emitted light and re-emits it at a lower energy. The result is a more efficient, albeit two-color, OLED device.

Finally, another approach involves use of a vertical cylindrical OLED device with metallic electrodes and a dielectric layer.

Accordingly, a need exists for other solutions to increasing light extraction in solid-state lighting devices and other light-emitting devices.

### SUMMARY

An edge-emitting OLED device, consistent with the present invention, includes a substrate and an organic electroluminescent layer overlaying the substrate surface. The organic electroluminescent layer forms an edge-emitting OLED. A plurality of optical microstructures are formed on the substrate and separated from the organic electroluminescent layer. Each of the optical microstructures defines turning optics for reflecting and redirecting light from the edge-emitting OLED.

A method of fabricating an edge-emitting OLED device, consistent with the present invention, includes the following steps: providing a substrate; applying a curable organic layer to the substrate surface for use in forming an edge-emitting OLED; forming a plurality of optical microstructures on the substrate and separated from the organic electroluminescent layer; curing the curable organic layer; and applying a metallic layer over the organic electroluminescent layer to form an electrode and over the optical microstructures to form turning optics for reflecting and redirecting light from the edge-emitting OLED.

### BRIEF DESCRIPTION OF THE DRAWINGS

The accompanying drawings are incorporated in and constitute a part of this specification and, together with the description, explain the advantages and principles of the invention. In the drawings,

FIG. 1 is a cross-sectional diagram illustrating an edge-emitting OLED with optical micro structures;

FIG. 2 is a cross-sectional diagram illustrating an edge- and top-emitting OLED with optical microstructures;

FIG. 3 is a cross-sectional diagram illustrating an edge-emitting OLED with optical micro structures;

FIG. 4 is a cross-sectional diagram illustrating an edge- and bottom-emitting OLED with optical microstructures;

FIG. 5 is a cross-sectional diagram illustrating an edge-emitting OLED with concave optical microstructures;

FIG. 6 is a cross-sectional diagram illustrating an edge-emitting OLED with convex optical microstructures;

FIG. 7a is a cross-sectional diagram illustrating a first exemplary pattern for fabricating edge-emitting OLEDs with optical microstructures;

FIG. 7b is a cross-sectional diagram illustrating a second exemplary pattern for fabricating edge-emitting OLEDs with optical microstructures;

FIGS. 8a-8d are top views illustrating the appearance of various optical microstructures for use with edge-emitting OLEDs;

FIGS. 9a-9d are perspective views illustrating the appearance of the optical microstructures shown in FIGS. 8a-8d;

FIG. 9e is a top view diagram of a serpentine layout of optical microstructures;

FIGS. 10a-10j are block diagrams illustrating an exemplary sequence of fabrication steps for producing an edge-emitting OLED with optical microstructures;

FIG. 11 is a diagram illustrating spatially modulated edge-emitting OLEDs with optical microstructures; and

FIG. 12 is a diagram illustrating edge-emitting OLEDs with optical microstructures used as an LCD backlight unit.

### DETAILED DESCRIPTION

Embodiments can provide for increased light extraction in OLED devices for higher light output in solid-state lighting or other devices such as displays. A microreplicated substrate includes edge-emitting OLEDs and microstructured turning optics to extract the light and reduce the amount of losses due to lightguiding. This type of microreplicated substrate can be provided as a rigid or flexible sheet for solid-state lighting applications, for example.

### Edge-Emitting OLEDs

An OLED is typically a thin film structure formed on a substrate such as glass, a transparent flexible film, or a flexible metal foil. The substrate for an OLED may comprise, for example, one of the following: an organic polymeric material; polyethylene terephthalate (“PET”); polyacrylates; polycarbonates; silicone; epoxy resins; silicone-functionalized epoxy resins; polyesters; polyimides; polyethersulfones; polyetherimide; polyethylene naphthalate (“PEN”); or other opaque or translucent materials. The substrate may also comprise impermeable materials such as, for example, stainless steel and metal foils. Examples of display device substrates, including flexible metal foils, are described in the following papers, all of which are incorporated herein by reference: H. S. Shin et al., “4.1 inch Top-Emission AMOLED on Flexible Metal Foil,” SID 05 DIGEST, pp. 1642-1645 (2005); X. L. Zhu et al., “Very Bright and Efficient Top-Emitting OLED with Ultra-Thin Yb as Effective Electron Injector,” SID 06 DIGEST, pp. 1292-1295 (2006); J. H. Cheon et al., “A 2.2-in. Top-Emission AMOLED on Flexible Metal Foil with SOG Planarization,” SID 06 DIGEST, pp. 1354-1357 (2006); H. K. Chung et al., “AMOLED Technology for Mobile Displays,” SID 06 DIGEST, pp. 1447-1450 (2006); D. U. Jin et al., “5.6-inch Flexible Full Color Top Emission AMOLED Display on Stainless Steel Foil,” SID 06 DIGEST, pp. 1855-1857 (2006); and A. Chwang et al., “Full Color 100 dpi AMOLED Displays on Flexible Stainless Steel Substrates,” SID 06 DIGEST, pp. 1858-1861 (2006).

A light-emitting layer of an organic electroluminescent (EL) material, such as a light-emitting polymer, and optional adjacent semiconductor layers are located between a cathode and an anode. An example of a light-emitting polymer layer is described in U.S. Pat. No. 6,605,483, which is incorporated herein by reference. The EL material can be sandwiched or interdigitated, for example, between the cathode and anode. The semiconductor layers may be hole injection (positive charge), electron injection (negative charge), hole blocking, electron blocking, hole transporting, or electron transporting, and they also comprise organic materials. The material for the light-emitting layer may be selected from many organic EL materials. The light emitting organic layer may itself include multiple sublayers, each comprising a different organic EL material. Organic EL materials can emit electromagnetic (“EM”) radiation having narrow ranges of wavelengths in the visible spectrum.

To achieve white light in one particular example, devices incorporate closely arranged OLEDs emitting blue, green, and red light, or complementary colors of light (e.g., blue and yellow). These colors are mixed to produce white light. In one configuration described in U.S. Pat. Nos. 5,294,869 and 5,294,870, these OLEDs are formed as adjacent pixels that are individually addressable. Separated areas of one or more organic EL materials and color conversion layers coupled to them are deposited on a patterned electrode that provides the capability to electrically control the individual pixels. The deposition of these layers is effected by a shadow mask comprising a plurality of walls that are first formed on the substrate by photolithography. The portions of the surface in the shadow of the walls do not receive vapor directed at an angle at such surface. Thus, the locations of the deposited areas are controlled by the heights of the walls and the angle of deposition.

OLEDs can include topographical features and can be formed as a matrix of rows and column, or as a series of long rows. The dimension of each topographical feature and the distance between two adjacent features typically correspond to the desired dimension of a pixel of the matrix display. For high-density, high-resolution information displays, the pixel dimension can be in the range from about 5 microns to about 100 microns. On the other hand, for general lighting purposes, the pixel area can be several square centimeters or greater. The height of the raised features is typically in the range from about 1 micron to about 100 microns, and more typically less than 10 microns. The OLEDs with turning optics can also be used as a backlight unit for a liquid crystal display (LCD) device, optionally spatially modulated.

Individual OLEDs can be built on top of the ridges (raised features) or in valleys between them. The OLEDs thus built can be addressed individually to display information or images represented by the collection of activated OLEDs for display devices. Typically, an OLED comprises at least an organic EL layer capable of emitting light when activated by a current with the organic EL layer being sandwiched or interdigitated between two conductor layers serving as an anode and a cathode.

To make an OLED, successive layers of an anode, an organic EL, and a cathode material are deposited on the substrate. ITO is typically used as the anode material, which should typically be a high work function in the range of about 4.5 eV to about 5.5 eV. ITO is substantially transparent to light transmission and allows at least 80% light transmission. Therefore, light emitted from the organic electroluminescent layer can easily escape through the ITO anode layer without being substantially attenuated. Other materials suitable for use as the anode layer include, for example, tin oxide, indium oxide, zinc oxide, indium zinc oxide, cadmium tin oxide, and mixtures thereof. In addition, materials used for the anode may be doped with aluminum or fluorine to improve charge injection property. Electrode layers may be deposited on the underlying element by physical vapor deposition, chemical vapor deposition, ion beam-assisted deposition, or sputtering. A thin, substantially transparent layer of a metal is also suitable.

More than one organic EL layer may be formed successively one on top of another, each layer comprising a different organic EL material that emits in a different wavelength range. Such a construction can facilitate a tuning of the color of the light emitted from the overall light-emitting display device. Furthermore, one or more additional layers may be included between electrodes to increase the efficiency of the overall device. These additional layers may also be deposited by physical vapor deposition or chemical vapor deposition. For example, these additional layers can serve to improve the injection (electron or hole injection enhancement layers) or transport (electron or hole transport layers) of charges into the organic EL layer. The thickness of each of these layers is typically kept to below about 500 nanometers (nm), more preferably below about 100 nm. Materials for these additional layers are typically low-to-intermediate molecular weight (less than about 2000) organic molecules. In some cases, a hole injection enhancement layer is formed between the anode layer and organic EL layer to provide a higher injected current at a given forward bias and/or a higher maximum current before the failure of the device. Thus, the hole injection enhancement layer facilitates the injection of holes from the anode. Suitable materials for the hole injection enhancement layer include, for example, materials disclosed in U.S. Pat. No. 5,998,803, incorporated herein by reference.

As an alternative, each OLED can further include a hole transport layer which is disposed between the hole injection enhancement layer and organic EL layer. The hole transport layer has the functions of transporting holes and blocking the transportation of electrons so that holes and electrons are optimally combined in organic EL layer. Materials suitable for the hole transport layer include, for example, materials disclosed in U.S. Pat. No. 6,023,371, incorporated herein by reference.

As another alternative, each OLED can include an additional layer disposed between the cathode layer and the organic EL layer. This additional layer has the combined function of injecting and transporting electrons to the organic EL layer. Materials suitable for the electron injecting and transporting layer include, for example, materials disclosed in U.S. Pat. No. 6,023,371.

In another aspect, a mixture of an organic EL material and a dye (host and emitter) is deposited between the electrodes of individual OLEDs. The dye absorbs a portion of EM radiation emitted by the organic EL material and emits EM radiation in a different wavelength range. Different dyes are used for different OLEDs to generate different colors. For example, dyes can be selected such that three adjacent OLEDs emit blue, green, and red colors, which in combination result in white light.

The following paper, incorporated herein by reference, describes an OLED that emits light laterally: A. Mikami et al., “High Efficiency Phosphorescent Organic Light-Emitting Devices Coupled with Lateral Color Conversion Layer,” SID 06 DIGEST, pp. 1376-1379 (2006).

The following papers, all of which are incorporated herein by reference, describe methods to extend the cavity dimensions of OLEDs: L.-S. Liao et al., “High-Efficiency Tandem Blue OLEDs,” SID 06 DIGEST, pp. 1197-1200 (2006); T. Maindron et al., “High Performance and High Stability PIN OLED,” SID 06 DIGEST, pp. 1189-1192 (2006); and T. K. Hatwar et al., “Low-Voltage White Tandem Structures for Fabricating RGBW AMOLED Displays,” SID 06 DIGEST, pp. 1964-1967 (2006).

The following papers, all of which are incorporated herein by reference, describe use of edge-emitting thick film electroluminescent (TFEL) devices: Y.-H. Lee et al., “A New Light Emitting Structure Using Edge Emission Reflected by Micro-Tip Reflectors,” Korean Institute of Science and Technology, pp. 41-42; Z. Kun et al., “TFEL Edge Emitter Array for Optical Image Bar Applications,” SID 86 DIGEST, pp. 270-272 (1986); and Y. H. Lee et al., “White-Light Emitting Thin-Film Electroluminescent Device Using Micromachined Structure,” IEEE Transaction on Electronic Devices, vol. 44, no. 1, pp. 40-44 (1997).

### Edge-Emitting OLEDs with Optical Microstructures

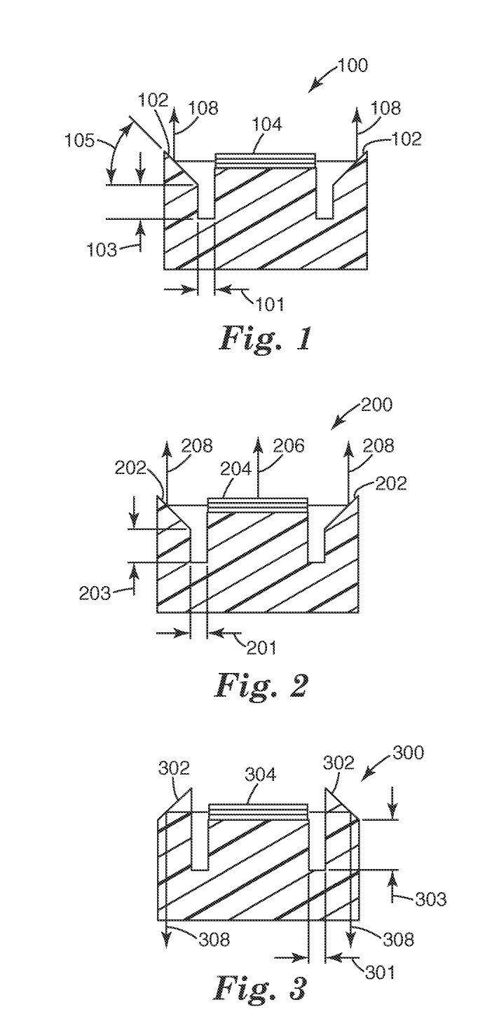

FIGS. 1-6 are cross-sectional diagrams illustrating edge-emitting OLED devices with optical microstructures. FIGS. 1-6 are not shown to scale and the dimensions can be adjusted based upon particular implementations. FIG. 1 represents an exemplary cross-section of a unit cell 100 of the device, and the unit cells are repeated to make a complete OLED solid-state lighting or display device. Unit cell 100 includes an edge-emitting OLED 104 producing light 108. Unit cell 100 also includes optical microstructures 102, separated from OLED 104 by an optional gap 101 having an optional depth 103, for reflecting and redirecting at least a portion of light 108. Optical microstructures 102 can function as turning optics to redirect the light from the OLED out of the top of the unit cell 100. The turning optics 102 are arranged at an angle 105 with respect to the light emitted from OLED 104, and angle 105 may or may not be constant over the device area, meaning that the turning optics can all have substantially the same angle 105 or they can have varying angles 105. In this manner, the entire device can be configured for directing light in different directions by fine-tuning the various angles for the turning optics. The angle 105 can be selected for a desired reflection and redirection of light 108, for example.

An aspect of this structure, as illustrated by unit cell 100, is self-alignment and compatibility with vacuum OLED material deposition. During the deposition process, the optional gap 101 can create the light-emitting edge of OLED 104 as well as the electrical isolation of the optical microstructures 102. In some cases, the OLED material is deposited uniformly over the microstructured area, even on the prism surfaces of optical microstructures 102, and a metallic layer is then deposited over the OLED material. The metallic layer provides a dual use as both an electrode for OLED 104 and reflective surface for the prisms, optical microstructures 102. One or both of the electrodes on optical microstructures 102 may functions as a reflective surface, and the OLED layers on the turning optics facet are inactive.

FIG. 2 illustrates another exemplary unit cell 200 of the self-aligned OLED in which the cathode is semitransparent so that emission takes place both through the cathode and along the edge. Unit cell 200 includes an edge-and top-emitting OLED 204 producing light 206 and 208. Unit cell 200 also includes optical microstructures 202 functioning as turning optics, separated from OLED 204 by an optional gap 201 having an optional depth 203, for reflecting and redirecting at least a portion of light 208. In this case, the cathode may comprise a thin metallic layer and a thicker layer of ITO. This mode as embodied in unit cell 200 efficiently captures waveguided light as well as light emitted normal to the device plane. Devices made with this construction may have a high ratio of the light-emissive area to the non-emissive area regardless of self-absorption or attenuation aspects.

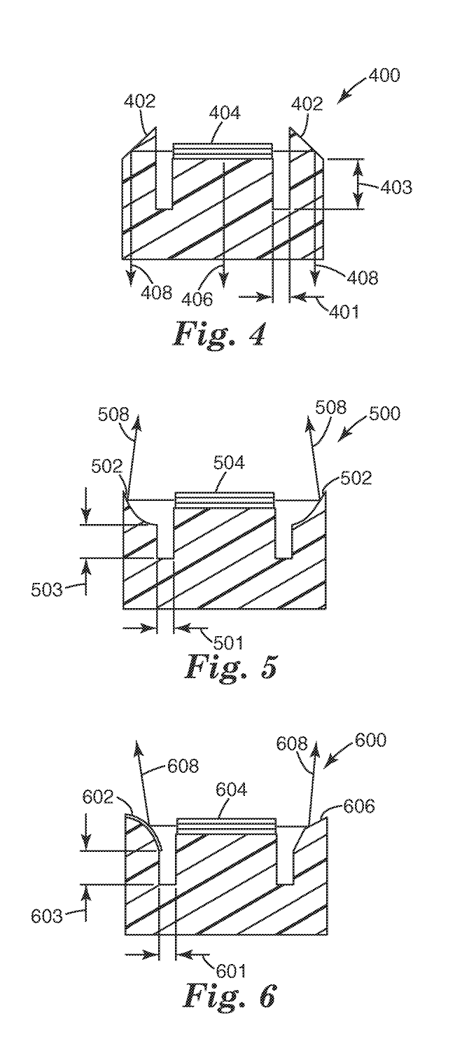

FIGS. 3 and 4 illustrate modes analogous to the unit cells shown in FIGS. 1 and 2 except that the optical microstructure prisms are angled in such a way as to direct the emitted light down through the substrate. FIG. 3 illustrates a unit cell 300 including an edge-emitting OLED 304 producing light 308. Unit cell 300 also includes optical microstructures 302 functioning as turning optics, separated from OLED 304 by an optional gap 301 having an optional depth 303, for reflecting and redirecting at least a portion of light 308. FIG. 4 illustrates a unit 400 including an edge- and bottom-emitting OLED 404 producing light 406 and 408. Unit cell 400 also includes optical microstructures 402 functioning as turning optics, separated from OLED 404 by an optional gap 401 having an optional depth 403, for reflecting and redirecting at least a portion of light 408. The unit cells of FIGS. 3 and 4 have transparent or semi-transparent bottom electrodes to enable both edge and bottom emission. The prisms are shaped to either focus or diffuse the edge-emitted light through the substrate.

FIGS. 5 and 6 illustrate unit cells where light is redirected at an angle, other than substantially 90°, with respect to the substrate. FIG. 5 illustrates a unit cell 500 including an edge-emitting OLED 504 producing light 508. Unit cell 500 also includes optical microstructures 502 functioning as turning optics, separated from OLED 504 by an optional gap 501 having an optional depth 503, for reflecting and redirecting at least a portion of light 508 at an inward angle with respect to the substrate. FIG. 6 illustrates a unit cell 600 including an edge-emitting OLED 604 producing light 608. Unit cell 600 also includes optical microstructures 602 and 606 functioning as turning optics, separated from OLED 604 by an optional gap 601 having an optional depth 603, for reflecting and redirecting at least a portion of light 608 at an outward angle with respect to the substrate. In addition, as illustrated in unit cell 600, the turning optics can be spherical such as optical microstructure 602, a combination of planar surfaces such as optical microstructure 606, or have an aspherical or other type of shape.

The construction of the unit cells illustrated in FIGS. 1-6 can be varied in a number of ways. The substrate can be designed with an array or distribution of different prism types. For example, the turning optics facets can be designed as elements of a composite lens such as a Fresnel lens so that the overall light emission is controlled over the device surface formed from many unit cells. The turning optics facets would together form the composite lens. In this manner, the emitted light can be collimated, diffused, or focused.

The size of the gap (101, 201, 301, 401, 501, and 601) between the OLED and optical microstructures can be adjusted based on the divergence of the emitted beam from the OLED edge. If the divergence is large, then the gap need be relatively small. The gap may also be adjusted based on the deposition angle and the shadowing observed during deposition. The size of the gap can be, for example, between about 0.01 micron and 100 microns. In certain cases, no gap is needed, meaning the gap can have a distance of zero or substantially zero.

The size of the depth (103, 203, 303, 403, 503, and 603) between the base of the optical microstructures and the bottom of the gap, when used, can be adjusted. The size of the depth can be, for example, between about 0.01 micron and 100 microns. In certain cases, no depth is needed, meaning the depth can have a distance of zero or substantially zero, particularly if no gap is used.

The angle of the turning optics in each of the unit cells (100, 200, 300, 400, 500, and 600), such as angle 105, can be adjusted for a desired reflection and redirection of light from the OLEDs in each unit cell. Also, the angles can be constant or variable over the device area, meaning that the turning optics can all have substantially the same angle or they can have varying angles. In this manner, the entire device can be configured for directing light in different directions by fine-tuning the various angles for the turning optics. In addition, the angles can be selectively varied across the device, along with use of concave or convex turning optics as shown in FIGS. 5 and 6, to form a Fresnel lens.

The turning optics (102, 202, 302, 402, 502, 602, and 606) for the unit cells can be formed from a variety of materials. For example, they can be formed from a metallic layer providing a reflective surface for reflecting and redirect the light from the OLEDs. Alternatively, they can formed from any material for provides for TIR. For example, if light 108 from OLED 104 impinges upon optical microstructure 102 at an angle less than the critical angle for TIR, then optical microstructure 102 can reflect and redirect light 108 as shown in FIG. 1. In that case, if the substrate is formed from an optical film using one of the exemplary substrates identified above, then the optical microstructures can provide for reflecting and redirecting light through TIR and need not be patterned with a metallic material. The use of TIR can even be used with the optical microstructures that reflect and direct light through the substrate, such as unit cell 300 shown in FIG. 3. In particular, optical microstructure 302 can reflect and redirect light 308 such that it impinges upon the bottom surface of the film at an angle of approximately 90°, which is greater than the critical angle for TIR and thus allows light 308 to escape the substrate.

The size of the light generation region of the OLEDs can be optimized so that the emitting area is a large fraction of the total surface, effectively creating a large aperture ratio device. The brightness of the device or regions within a device can be determined geometrically by considering the size of the gap, the light generation region, and the optical microstructures, and by altering the ratio of light emitted from the face and edges of the light emitting region by changing the optical density of the metallic cathode. Another method to determine the device or region brightness involves changing the edge-to-land ratio in the two-dimensional design of the device, for exampling increasing the edge-to-land ratio by making the edge a structured shape, for example a zig-zag pattern. The use of a structured edge also increases the amount of light emitted through the edge in the plane of the device. With such a structure, the distance from the point of emission to the nearest edge is reduced and, therefore, the number of reflections before the light escapes from the edge is decreased. Use of these methods allows for a range of brightness within a single device operating at a single current density and voltage. This range of brightness can be useful in solid-state lighting, for example.

Another variant of the unit cells involves the combination of the edge-emitting structure with a tandem or stacked OLED device construction. This structure can be used as a way of creating a white light emitting device from red, green, and blue light-emitting layers. It is also a way to extend the vertical cavity dimensions for a monochromatic emitter so that the cavity between reflective anode and cathode is tuned to the wavelength of emission. The monochromatic emitter can be useful in solid-state lighting, for example, to obtain white light for indoor lighting applications. Alternatively, the unit cells can be constructing of OLEDs emitting one substantially uniform color for solid-state lighting when a particular color is desired. In addition, if the unit cells are made with a repeating microreplicated structure of red, green, and blue light-emitting OLEDs, the individual unit cells can be controlled to produce a variety of colors for lighting effects in solid-state lighting. For example, through control of which unit cells are activated, a variety of colors can be selectively produced, providing a user with the flexibility to select particular colors of light in solid-state lighting applications.

### Device Fabrication

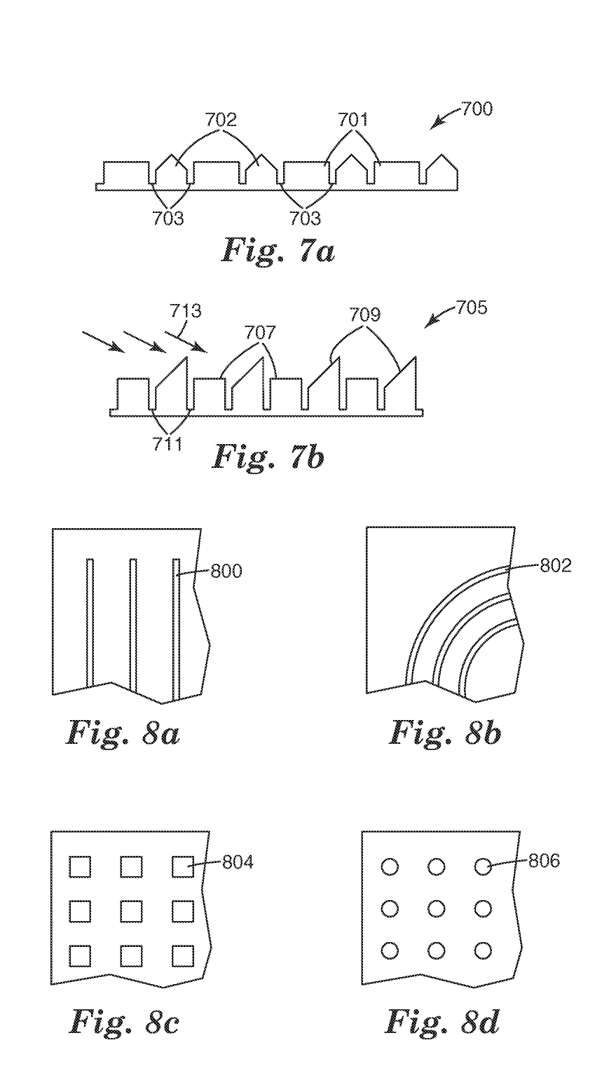

Several patterns are possible for edge-emitting microstructured OLED devices based upon the same structural motif 700, as shown in FIG. 7a. The one-dimensional pattern comprises a series of linear OLED surfs 701 with turning optics 702 opposite each edge. Each surf and turning optics together form a unit cell such as those illustrated in FIGS. 1-6. A trough 703, corresponding with the gaps described with respect to FIGS. 1-6, separates the surfs to form an emitting OLED edge between the two elements, when a gap is used.

FIG. 7b is a cross-sectional diagram illustrating an alternative pattern, structural motif 705, for fabricating edge-emitting OLEDs with optical microstructures. The one-dimensional alternative pattern 705 comprises a series of linear OLED surfs 707 with turning optics 709 opposite one edge of each OLED surf. Each surf and turning optic together form a unit cell such as those illustrated in FIGS. 1-6, except with turning optics on only one side of each OLED surf. A trough 711, corresponding with the gaps described with respect to FIGS. 1-6, separates the surfs to form an emitting OLED edge between the two elements, when a gap is used. The use of only one turning optic for each OLED surf may provide for easier fabrication using angular deposition, as represented by arrows 713, to deposit the material for the turning optics and electrodes, for example. An angle evaporation process for depositing materials to make an OLED device is described in U.S. Pat. Nos. 6,965,198 and 6,791,258, both of which are incorporated herein by reference.

The structural motifs 700 and 705 can be used to generate a number of two-dimensional patterns including a linear array, a circular array, and several arrays in which the prismatic elements are isolated grid-like structures. In the circular array case, a linear grid is superimposed over the array as a means of conducting current to the periphery of the device.

The structural motifs 700 and 705 can be formed as a microreplicated sheet as the substrate, for example. In particular, the unit cells shown in FIGS. 1-6, or other unit cells, can be repeated across a substrate using a microreplication process to make the sheet from a microreplicated tool. The microreplicated sheet with the unit cells can be useful in solid-state lighting devices. Processes to make a microreplicated tool for use in making optical films are described in U.S. Pat. Nos. 6,354,709 and 6,581,286, both of which are incorporated herein by reference. When used for solid-state lighting, the sheet can be ceiling tiles, for example, that also function to provide light for indoor lighting applications. If the sheet is made from a flexible material and used for solid-stating lighting, the sheet can be wrapped around objects to provide decorative lighting effects, possibly including various colors, for example. If the sheet is weather resistant, it can also be used to provide outdoor solid-state lighting.

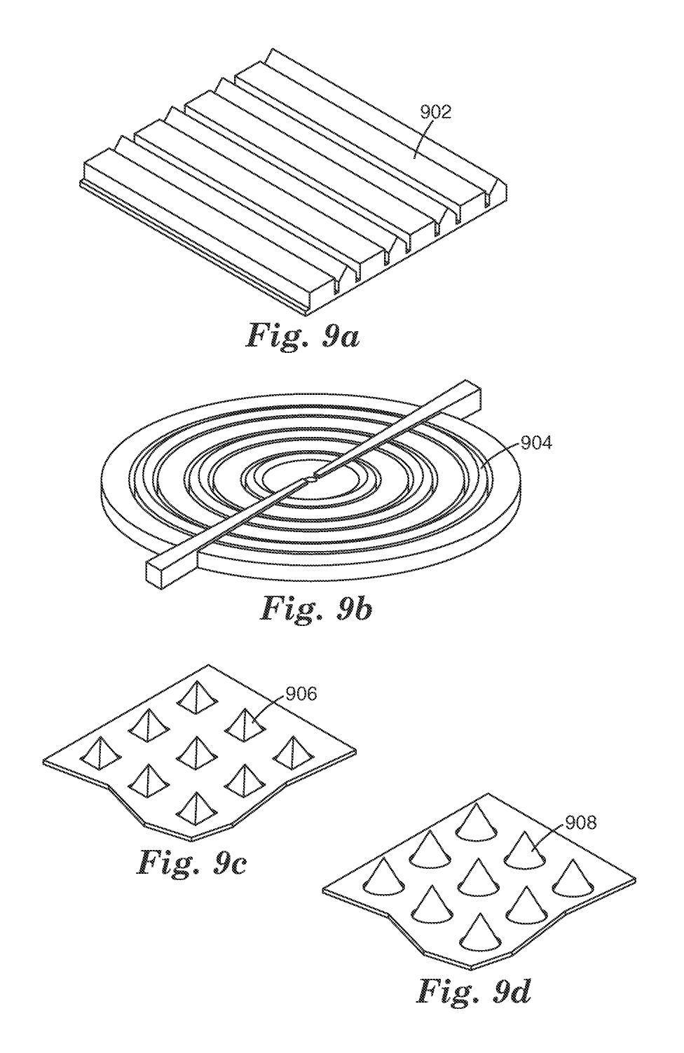

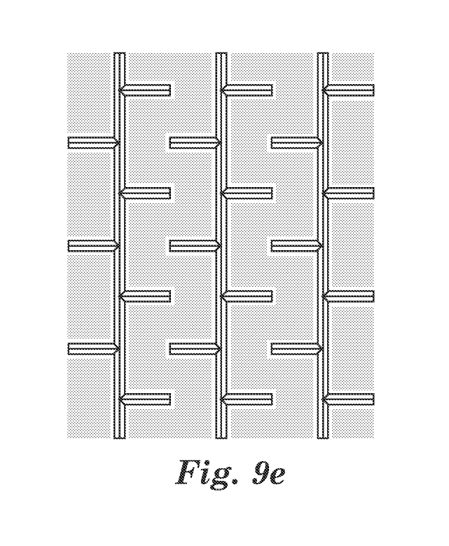

FIGS. 8a-8d are top views illustrating examples of the appearance of various optical microstructures for use in unit cells according to various OLED embodiments. In particular, FIGS. 8a-8d illustrate, respectively, linear prisms 800, circular prisms 802, pyramidal prisms 804, and conical prisms 806. FIGS. 9a-9d are perspective views corresponding with FIGS. 8a-8d and illustrating the appearance of these exemplary optical microstructures. In particular, FIGS. 9a-9d illustrate, respectively, a linear OLED array 902, a circular OLED array 904, a pyramidal OLED array 906, and a conical OLED array 908. FIG. 9e is a top view diagram of a serpentine layout of optical microstructures. In the serpentine layout, the triangular raised features form the turning optics, and the OLEDs are arranged in a corresponding layout between them.

FIGS. 7a, 7b, 8a-8d, and 9a-9e are not shown to scale and the dimensions can be adjusted based upon particular implementations.

An exemplary device fabrication method to make edge-emitting OLEDs with optical microstructures can involve use of conventional shadow mask deposition of each layer, the anode and cathode contacts, EL material, and turning optics.

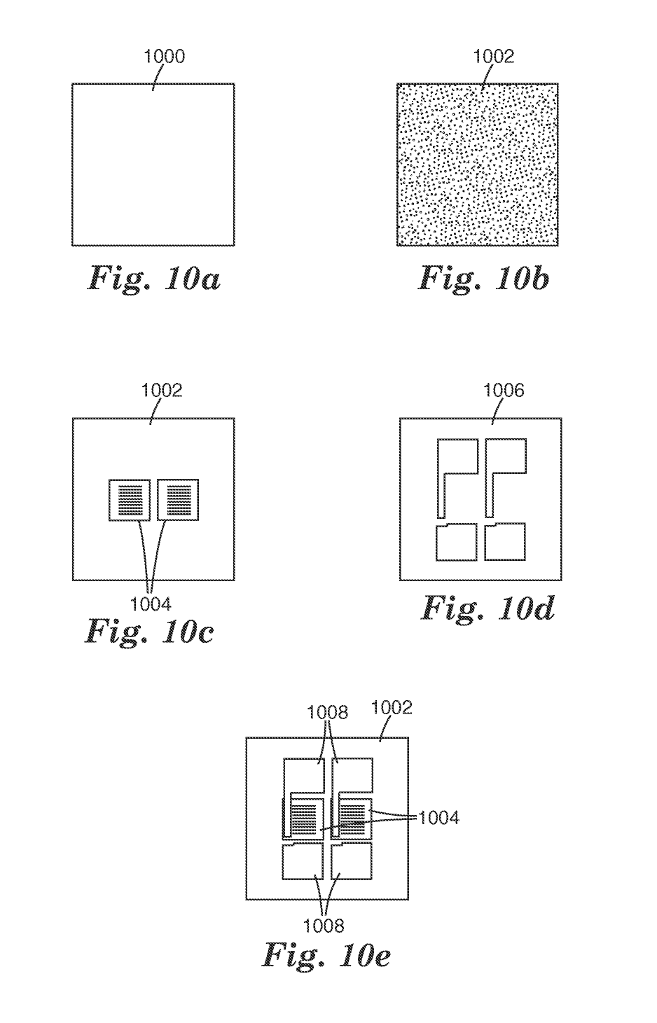

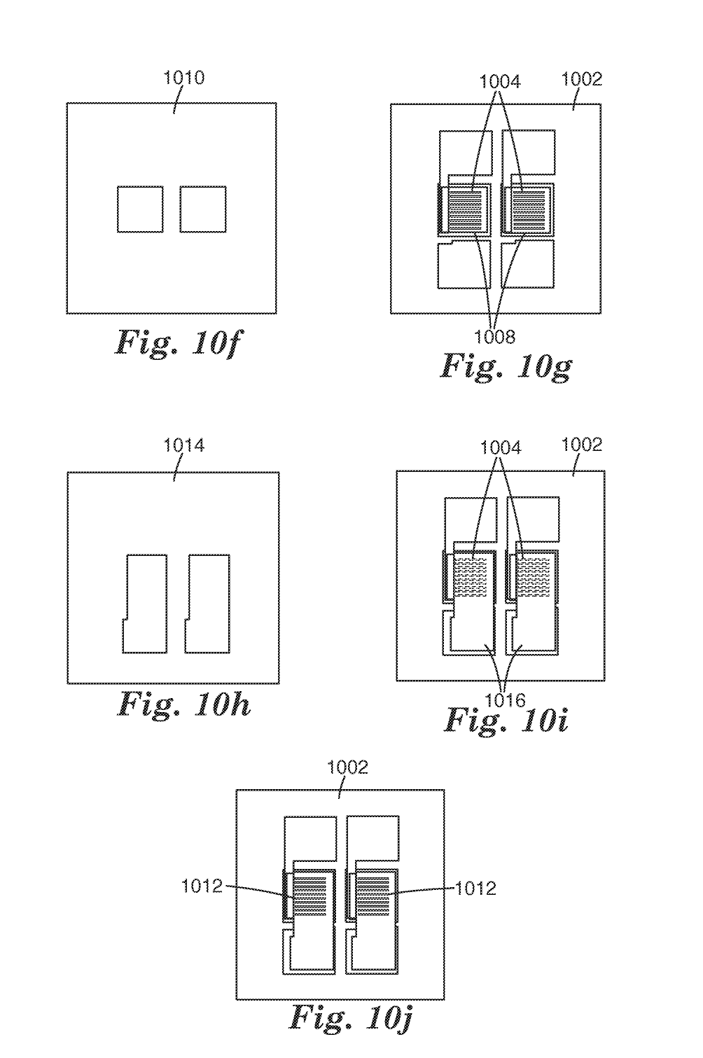

Table 1 describes steps for another exemplary device fabrication method to make edge-emitting OLEDs with optical microstructures, and FIGS. 10a-10j are block diagrams illustrating the exemplary sequence of fabrication steps. Other suitable methodologies are possible.

TABLE 1

| Step | Description |
|---|---|
| 1 | Provide a 50 millimeter (mm) × 50 mm glass substrate 1000, as illustrated in |
| | FIG. 10a. |
| 2 | Spin coat UV curable polyimide or benzocyclobutane (BCB) 1002 onto the glass |
| | substrate and beta bake to remove solvent, as illustrated in FIG. 10b. |
| 3 | Microemboss the OLED structure into two or more pixel regions 1004 using a |
| | microreplication tool, photocure the polymer to hold the structure, and then bake |
| | to imidize or fully cure, as illustrated in FIG. 10c. |
| 4 | Vapor deposit metal anode and cathode contacts using shadow mask 1 (1006), |
| | where the anode contact 1008 extends to the pixel region, as illustrated in FIGS. |
| | 10d and 10e. |
| 5 | Vapor deposit an OLED stack, including a reflective anode, using shadow mask |
| | 2 (1010), as illustrated in FIGS. 10f and 10g. Cathode deposition is an option |
| | during this step. |
| 6 | Vapor deposit an OLED cathode contact 1016 using shadow mask 3 (1014), as |
| | illustrated in FIGS. 10h and 10i. |
| 7 | Optionally test the device by applying a voltage across it; light should be visible |
| | at the turning optics 1012 or, if the cathodes are semitransparent, in the entire |
| | pixel region, as illustrated in FIG. 10j. |

For this exemplary fabrication method, the substrate can be any barrier substrate such as stainless steel, foil laminated polyimide, glass, ceramic, or others as described above. The organic coating may be a photopolymerizable polyimide, a photopolymerizable benzocyclobutane, or any other material that is compatible with both the microreplication process and OLEDs. The material should be thermally stable and free of volatile components.

The microstructured devices may be encapsulated. Encapsulation techniques known in the art for top and bottom emitting OLEDs may be used, for example multilayer coatings or vapor deposited inorganic coatings. The limited exposure of the edge should decrease device degradation regardless of encapsulation technique.

Table 2 describes steps for another exemplary device fabrication method to make edge-emitting OLEDs with optical microstructures using a laser induced thermal imaging (LITI) process. The LITI process involves use of a donor film having a donor substrate, a light-to-heat conversion (LTHC) layer over the substrate, and a transfer layer over the LTHC layer. For thermal transfer using radiation (e.g., light) in a LITI process, a variety of radiation-emitting sources can be used with a LITI donor film. For analog techniques (e.g., exposure through a mask), high-powered light sources (e.g., xenon flash lamps and lasers) are useful. For digital imaging techniques, infrared, visible, and ultraviolet lasers are particularly useful. Suitable lasers include, for example, high power (e.g. ≧100 mW) single mode laser diodes, fiber-coupled laser diodes, and diode-pumped solid state lasers (e.g., Nd:YAG and Nd:YLF). Laser exposure dwell times can be in the range from, for example, about 0.1 microsecond to 100 microseconds and laser fluences can be in the range from, for example, about 0.01 J/cm² to about 1 J/cm². During imaging, the thermal transfer layer is typically brought into intimate contact with a permanent receptor (substrate for the unit cells) adapted to receive at least a portion of the transfer layer. In at least some instances, pressure or vacuum may be used to hold the thermal transfer layer in intimate contact with the receptor. A radiation source may then be used to heat the LTHC layer or other layers containing radiation absorbers in an image-wise fashion (e.g., digitally or by analog exposure through a mask) to perform image-wise transfer of the transfer layer from the thermal transfer layer to the receptor according to a pattern.

Various layers of an exemplary LITI donor film, and methods to image it, are more fully described in U.S. Pat. Nos. 6,866,979; 6,586,153; 6,468,715; 6,284,425; and 5,725,989, all of which are incorporated herein by reference.

TABLE 2

| Step | Description |
|---|---|
| 1 | Provide a substrate. |
| 2 | Vapor deposit the first electrode on the substrate and optionally |
| | deposit a metallic material on the optical microstructure when |
| | used for the turning optics. |
| 3 | LITI pattern the organic layer over the first electrode. |
| 4 | LITI pattern at least part of the organic stack and the second |
| | electrode over the organic layer using a smaller line width than the |
| | organic layer. |

Spatial Modulation and Backlights

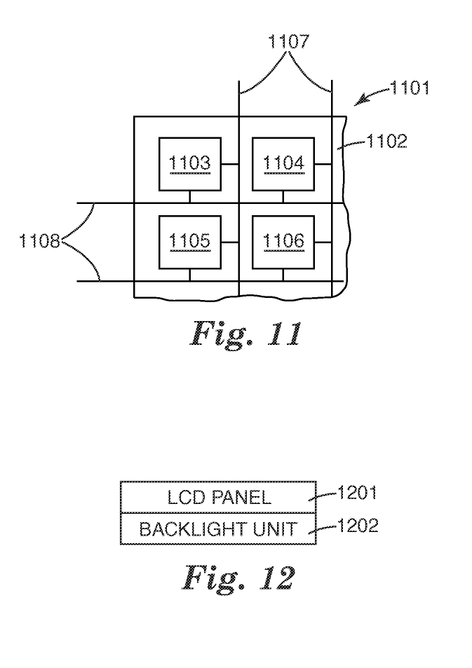

FIG. 11 is a diagram illustrating a device 1101 having spatially modulated edge-emitting OLEDs with optical microstructures. Device 1101 includes a substrate 1102 supporting a plurality of edge-emitting OLEDs with optical microstructures 1103, 1104, 1105, and 1106, each of which may correspond with the structures described above with respect to FIGS. 1-6, 7a, and 7b. Each of the OLED devices 1103-1106 can be individually controlled as represented by lines 1107 and 1108, which would provide electrical connections to the anodes and cathodes in devices 1103-1106. Device 1101 can include any number of OLED devices 1103-1106 with electrical connections, and substrate 1102 can be scaled to accommodate them. The individual control of devices 1103-1106, via connections 1107 and 1108, can provide for spatial modulation of them such that they are individually or in groups lighted in a particular sequence or pattern. Device 1101 can be used in solid-state light, for example, on a rigid or flexible substrate 1102.

FIG. 12 is a diagram illustrating edge-emitting OLEDs with optical microstructures used as an LCD backlight unit 1202 for an LCD panel 1201. Backlight unit 1202 may correspond with the structures described above with respect to FIGS. 1-6, 7a, and 7b, and it can include a diffuser or other films between the backlight unit 1202 and LCD panel 1201. The backlight unit 1202 can alternatively be implemented with the spatially modulated light panel shown in FIG. 11. LCD panel 1201 typically includes the entire LCD device except the backlight and drive electronics. For example, LCD panel 1201 typically includes the backplane (subpixel electrodes), front and back plates, liquid crystal layer, color filter layer, polarizing filters, and possibly other types of films. Use of edge-emitting OLEDs with optical microstructures as a backlight may provide for a thin, low power backlight for LCDs. An example of LCD panel components and a modulated backlight unit are described in the following paper, which is incorporated herein by reference: “High Dynamic Range Liquid Crystal Displays,” HDR for LCD Whitepaper V1.1, BrightSide Technologies Inc., Vancouver, B.C., Canada (February 2006).

1. An edge-emitting organic light emitting diode (OLED) device, comprising:
a substrate;
an organic electroluminescent layer overlaying a surface of the substrate, the organic electroluminescent layer forming an edge-emitting OLED; and
a plurality of optical microstructures formed on the substrate and separated from the organic electroluminescent layer, wherein each of the optical microstructures defines turning optics for reflecting and redirecting light from the edge-emitting OLED.

2. The OLED device of claim 1, wherein the substrate comprises one of the following materials: a metal; a metal foil laminated to a polymer film; a metal-coated polymer film; a ceramic; a glass; or a flexible metal foil.

3. The OLED device of claim 1, wherein the substrate comprises an optically transmissive material.

4. The OLED device of claim 1, wherein the organic electroluminescent layer is derived from a photopolymerizable chemical compound.

5. The OLED device of claim 1, wherein the plurality of optical microstructures comprises one of the following: a linear array of prisms; a circular array of prisms; a rectangular array of pyramidal prisms; or a rectangular array of conical prisms.

6. The OLED device of claim 1, wherein the optical microstructures are separated from the organic electroluminescent layer by a gap between about 0.01 micron and 100 microns.

7. The OLED device of claim 1, wherein each of the turning optics comprises one of the following: concave turning optics; or convex turning optics.

8. The OLED device of claim 1, further comprising an electrode contact layer overlaying the organic electroluminescent layer.

9. The OLED device of claim 8, wherein the electrode contact layer comprises an optically transmissive material.

10. The OLED device of claim 1, further comprising an encapsulating layer overlaying the organic electroluminescent layer.

11. The OLED device of claim 10, wherein the encapsulating layer is optically transmissive.

12. The OLED device of claim 1, wherein the electroluminescent layer is structured to emit light through at least one of the substrate, the encapsulating layer, or the edge-emitting light element.

13. The OLED device of claim 1, wherein the substrate comprises a microreplicated sheet.

14. The OLED device of claim 1, wherein the organic electroluminescent layer emits a substantially uniform color of light for solid-state lighting.

15. The OLED device of claim 1, wherein the plurality of optical microstructures together form a composite lens.

16. A method of fabricating an edge-emitting organic light emitting diode (OLED) device, comprising the steps of:
providing a substrate;
applying a curable organic layer to a surface of the substrate for use in forming an edge-emitting OLED;
forming a plurality of optical microstructures on the substrate and separated from the organic electroluminescent layer;
curing the curable organic layer; and
applying a metallic layer over the organic electroluminescent layer to form an electrode contact layer and over the optical microstructures to form turning optics for reflecting and redirecting light from the edge-emitting OLED.

17. The method of claim 16, wherein the substrate comprises an optically transmissive material.

18. The method of claim 16, wherein the plurality of optical microstructures comprise one of the following: a linear array of prisms; a circular array of prisms; a rectangular array of pyramidal prisms; or a rectangular array of conical prisms.

19. The method of claim 16, wherein each of the turning optics comprises one of the following: concave turning optics; or convex turning optics.

20. The method of claim 16, wherein the electrode contact layer comprises an optically transmissive material.

21. The method of claim 16, further comprising the step of applying an encapsulating layer overlaying the curable organic layer.

22. The method of claim 21, wherein the encapsulating layer is optically transmissive.

23. The method of claim 16, wherein the curable organic layer is structured to emit light through at least one of the substrate, the encapsulating layer, or the edge-emitting light element.

24. A liquid crystal display (LCD) device, comprising:
an LCD panel; and
a backlight unit adjacent the LCD panel, the backlight unit comprising:
a substrate;
an organic electroluminescent layer overlaying a surface of the substrate, the organic electroluminescent layer forming an edge-emitting organic light emitting diode (OLED); and
a plurality of optical microstructures formed on the substrate and separated from the organic electroluminescent layer, wherein each of the optical microstructures defines turning optics for reflecting and redirecting light from the edge-emitting OLED.
